(19) United States
(12) Patent Application Publication
(10) Pub. No.: US 2024/0292762 A1
(43) Pub. Date: Aug. 29, 2024

(54) PHASE CHANGE MATERIAL

(71) Applicant: NIPPON ELECTRIC GLASS CO., LTD., Otsu-shi, Shiga (JP)

(72) Inventors: Yoshimasa MATSUSHITA, Otsu-shi (JP); Fumio SATO, Otsu-shi (JP)

(21) Appl. No.: 18/576,757

(22) PCT Filed: Jul. 26, 2022
(86) PCT No.: PCT/JP2022/028790

§ 371 Date: Jan. 5, 2024

(30) Foreign Application Priority Data
Jul. 29, 2021 (JP) 2021-124132

(51) Int. Cl. H10N 70/20; H10B 63/10; H10N 70/00

(52) U.S. Cl. CPC H10N 70/231; H10B 63/10; H10N 70/8828

(57) ABSTRACT

The present invention provides a phase change material suitable for capacity increase. The phase change material contains, in at %, from 1% to 40% of Ge, from 40% to 90% of Te, and from 0% to less than 5% of Sb, and further contains from 1% to 59% of one or more selected from Si, Al, Ga, Sn, Bi, Cu, Ag, Zn, Y, In, Ca, and Mg.

### TECHNICAL FIELD

The present invention relates to a phase change material.

### BACKGROUND ART

Development of phase change memory, which is a next-generation memory, is underway. Phase change memory is a non-volatile memory that records information by utilizing the difference in electrical resistance between the amorphous state and the crystalline state of the phase change material used. Phase change memory is attracting attention because of its high speed and large capacity.

Ge—Sb—Te-based phase change materials such as Ge₂₂Sb₂₂Te₅₆ (GST) have been widely used in phase change memories (Patent Document 1).

### CITATION LIST

### Patent Literature

Patent Document 1: JP 2013-536983 T

### SUMMARY OF INVENTION

### Technical Problem

GST has a low crystallization temperature, and thus its amorphous state tends to become unstable at high temperatures. Also, GST has a high melting point in the crystalline state, and a large amount of energy is required for the phase change from the crystalline state to the amorphous state. Therefore, power consumption tends to increase. When the power consumption increases, the temperature of GST tends to increase, and thus the amorphous state of GST tends to become even more unstable. This makes it difficult to further increase the capacity of phase change memories in which GST is used.

In view of the above, an object of the present invention is to provide a phase change material suitable for capacity increase.

### Solution to Problem

Each aspect of the phase change material for solving the aforementioned problem will be described.

A phase change material according to Aspect 1 contains, in at %, from 1% to 40% of Ge, from 40% to 90% of Te, and from 0% to less than 5% of Sb, and further contains from 1% to 59% of one or more selected from Si, Al, Ga, Sn, Bi, Cu, Ag, Zn, Y, In, Ca, and Mg.

A phase change material according to Aspect 2 is the phase change material in Aspect 1 in which Te/Ge, a content ratio of Te to Ge, is preferably from 2 to 8.

A phase change material according to Aspect 3 is the phase change material in Aspect 1 or Aspect 2 in which Sb+As is preferably from 0% to less than 5%.

A phase change material according to Aspect 4 is the phase change material in any one of Aspect 1 to Aspect 3 having a crystallization temperature Tx of preferably 150° C. or higher.

A phase change material according to Aspect 5 is the phase change material in any one of Aspect 1 to Aspect 4 having a crystalline melting point Tm of preferably 600° C. or lower.

A phase change material according to Aspect 6 is the phase change material in any one of Aspect 1 to Aspect 5 in which Δ(Tm−Tx), a difference between the crystalline melting point Tm and the crystallization temperature Tx, is preferably 400° C. or lower.

A phase change material according to Aspect 7 contains, in at %, from 1% to 40% of Ge, from 40% to 90% of Te, from 41% to 99% of Ge+Te, and from 0% to less than 5% of Sb, wherein Δ(Tm−Tx), a difference between the crystalline melting point Tm and the crystallization temperature Tx, is 400° C. or lower.

A phase change material according to Aspect 8 contains, in at %, from 1% to 40% of Ge, from 40% to 90% of Te, from 41% to 99% of Ge+Te, from 0% to less than 5% of Sb, and from 0% to 59% of Ga, in which, when in a crystalline state, contains at least one type of crystal selected from GeTe₄, GeTe, Te, and Ga₂Te₃.

A target according to Aspect 9 uses the phase change material in any one of Aspect 1 to Aspect 8.

A thin film according to Aspect 10 uses the phase change material in any one of Aspect 1 to Aspect 8.

A memory element according to Aspect 11 includes the phase change material in any one of Aspect 1 to Aspect 8.

A memory device according to Aspect 12 includes the memory element in Aspect 11.

A method according to Aspect 13 is a method of recording information, the method including a step of recording information by applying a voltage to a memory layer including a phase change material and changing a phase of the memory layer from a first state to a second state, in which the memory layer includes a phase change material containing, in at %, from 1% to 40% of Ge, from 40% to 90% of Te, and from 0% to less than 5% of Sb, and further contains from 1% to 59% of one or more selected from Si, Al, Ga, Sn, Bi, Cu, Ag, Zn, Y, In, Ca, and Mg.

A method according to Aspect 14 is the method in Aspect 13 in which, in the step of recording information, preferably at least one type of crystal selected from GeTe₄. GeTe, Te, and Ga₂Te₃ is precipitated.

### Advantageous Effects of Invention

The present invention can provide a phase change material suitable for capacity increase.

### BRIEF DESCRIPTION OF DRAWINGS

FIG. 1 is a schematic cross-sectional view of a memory element according to a first embodiment according to the present invention.

FIG. 2 is a schematic cross-sectional view of a memory element according to a second embodiment according to the present invention.

FIG. 3 is a schematic cross-sectional view of a memory element according to a third embodiment according to the present invention.

FIG. 4 is a schematic cross-sectional view of a memory element according to a fourth embodiment according to the present invention.

FIG. 5 is a schematic cross-sectional view of a memory element according to a fifth embodiment according to the present invention.

FIG. 6 is a schematic cross-sectional view of a memory element according to a sixth embodiment according to the present invention.

FIG. 7 is a schematic cross-sectional view of a memory element according to a seventh embodiment according to the present invention.

FIG. 8 is a schematic cross-sectional view of a memory element according to an eighth embodiment according to the present invention.

FIG. 9 is a schematic cross-sectional view of a memory element according to a ninth embodiment according to the present invention.

FIG. 10 is a schematic cross-sectional view of a memory element according to a tenth embodiment according to the present invention.

FIG. 11 is a schematic cross-sectional view of a memory element according to an eleventh embodiment according to the present invention.

FIG. 12 is a schematic cross-sectional view of a memory element according to a twelfth embodiment according to the present invention.

FIG. 13 is a schematic cross-sectional view of a memory element according to a thirteenth embodiment according to the present invention.

FIG. 14 is a schematic cross-sectional view of a memory element according to a fourteenth embodiment according to the present invention.

FIG. 15 is a schematic cross-sectional view of a memory element according to a fifteenth embodiment according to the present invention.

FIG. 16 is a schematic cross-sectional view of a memory element according to a sixteenth embodiment according to the present invention.

FIG. 17 is a schematic cross-sectional view of a memory element according to a seventeenth embodiment according to the present invention.

FIG. 18 is a schematic cross-sectional view of a memory element according to an eighteenth embodiment according to the present invention.

FIG. 19 is a schematic cross-sectional view of a memory element according to a nineteenth embodiment according to the present invention.

FIG. 20 is a schematic three-dimensional view of a memory element according to an embodiment according to the invention.

### DESCRIPTION OF EMBODIMENTS

Preferred embodiments will be described below. However, the following embodiments are merely examples, and the present invention is not limited to the following embodiments.

### Phase Change Material

A phase change material according to the present invention contains, in at %, from 1% to 40% of Ge, from 40% to 90% of Te, and from 0% to less than 5% of Sb, and further contains from 1% to 59% of one or more selected from Si, Al, Ga, Sn, Bi, Cu, Ag, Zn, Y, In, Ca, and Mg. Reasons for defining the composition as such and the content of each component will be described below. In the description below, “%” means “at %” unless otherwise indicated.

Ge is an essential component for increasing the crystallization temperature and stabilizing the amorphous state of the phase change material. The content of Ge is from 1% to 40%, preferably from 1% to 39%, from 2% to 35%, from 2% to 30%, from 5% to 30%, from 7.5% to 30%, from 7.5% to 25%, or from 10% to 25%, and particularly preferably from 10% to 20%. When the content of Ge is too small, the amorphous state tends to become unstable. In addition, the GeTe₄ crystals described later are less likely to precipitate. When the content of Ge is too large, the crystalline melting point tends to be too high.

Te is an essential component constituting the phase change material. The content of Te is from 40% to 90%, preferably from 45% to 90%, from 47% to 90%, from 50% to 85%, from 50% to 82.5%, from 55% to 82.5%, from 60% to 82.5%, from 60% to 80%, or from 62.5% to 80%, and particularly preferably from 65% to 80%. When the content of Te is too small, the crystallization temperature decreases, and the amorphous state tends to become unstable. When the content of Te is too large, the crystallization temperature also decreases, and the amorphous state also tends to become unstable.

The content of Ge+Te (the total amount of Ge and Te) is preferably from 41% to 99%, from 45% to 99%, from 50% to 99%, from 50% to 98%, from 55% to 97%, from 60% to 96%, from 65% to 95%, or from 70% to 95%, and particularly preferably from 75% to 95%.

Si, Al, Ga, Sn, Bi, Cu, Ag, Zn, Y, In, Ca, and Mg are components that tend to stabilize the amorphous state of the phase change material. Therefore, the phase change material according to the present invention particularly preferably contains one or more components selected from Si, Al, Ga, Sn, Bi, Cu, Ag, Zn, Y, In, Ca, and Mg in an amount of from 1% to 59%, preferably from 1% to 58%, from 1% to 55%, from 1% to 50%, from 1% to 45%, from 1% to 40%, from 1% to 35%, from 1% to 30%, from 1% to 25%, from 1% to 20%, from 1% to 15%, from 2% to 15%, or from 2.5% to 15%, and particularly preferably from 2.5% to 10%. When the content of these components is too large, the amorphous state tends to become unstable. The content of Si+Al+Ga+Sn+Bi+Cu+Ag+Zn+Y+In+Ca+Mg (the total amount of Si, Al, Ga, Sn, Bi, Cu, Ag, Zn, Y, In, Ca, and Mg) is from 1% to 59%, preferably from 1% to 58%, from 1% to 55%, from 1% to 50%, from 1% to 45%, from 1% to 40%, from 1% to 35%, from 1% to 30%, from 1% to 25%, from 1% to 20%, from 1% to 15%, from 2% to 15%, or from 2.5% to 15%, and particularly preferably from 2.5% to 10%. Note that in the present invention, “x+y+z+ . . . ” refers to the total content of the components. Here, not every component has to be contained as an essential component, and there may be a component that is not contained (having a content of 0%). In addition, “x+y+z+ . . . from A % to B %” includes, for example, “x=0%, y+z+ . . . from A % to B %” and “x=0%, y=0%, z+ . . . from A % to B %”.

Among the above components, Ga is a component that tends to increase the crystallization temperature and stabilize the amorphous state. As will be described later, Ga is also a component that tends to reduce Δ(Tm−Tx), a temperature difference between the crystallization temperature Tx and the crystalline melting point Tm. The content of Ga is preferably from 0% to 59%, from 1% to 59%, from 1% to 58%, from 1% to 55%, from 1% to 50%, from 1% to 45%, from 1% to 40%, from 1% to 35%, from 1% to 30%, from 1% to 25%, from 1% to 20%, from 1% to 15%, from 2% to 15%, or from 2.5% to 15%, and particularly preferably from 2.5% to 10%. When the content of Ga is too large, the amorphous state tends to become unstable.

Among the above components, Ag is a component that tends to stabilize the amorphous state. As will be described later, Ag is also a component that tends to reduce Δ(Tm−Tx), the temperature difference between the crystallization temperature Tx and the crystalline melting point Tm. The content of Ag is preferably from 0% to 59%, from 1% to 59%, from 1% to 58%, from 1% to 55%, from 1% to 50%, from 1% to 45%, from 1% to 40%, from 1% to 35%, from 1% to 30%, from 1% to 25%, from 1% to 20%, from 1% to 15%, from 2% to 15%, or from 2.5% to 15%, and particularly preferably from 2.5% to 10%. When the content of Ag is too large, the amorphous state tends to become unstable.

The content of Ga+Ag (the total amount of Ga and Ag) is preferably from 1% to 59%, from 1% to 58%, from 1% to 55%, from 1% to 50%, from 1% to 45%, from 1% to 40%, from 1% to 35%, from 1% to 30%, from 1% to 25%, from 1% to 20%, from 1% to 15%, from 2% to 15%, or from 2.5% to 15%, and particularly preferably from 2.5% to 10%. This makes it easy to stabilize the amorphous state, increase the crystallization temperature, and reduce Δ(Tm−Tx).

Sb is a component that tends to lower the crystallization temperature of the phase change material. As such, the content of Sb is from 0% to less than 5%, preferably from 0% to 4%, or from 0% to 3%, and particularly preferably from 0% to 2%.

In addition to the components described above, the phase change material according to the present invention may contain the following components.

F, Cl, Br, and I are components that tend to stabilize the amorphous state of the phase change material. The content of F+Cl+Br+I (the total amount of F, Cl, Br, and I) is preferably from 0% to 40%, from 0% to 30%, or from 0% to 20%, and particularly preferably from 0% to 10%. When the content of F+Cl+Br+I is too large, the amorphous state tends to be unstable. In addition, the weather resistance tends to decrease. Note that, the content of each component of F, Cl, Br, and I is preferably from 0% to 40%, from 0% to 30%, or from 0% to 20%, and particularly preferably from 0% to 10%.

B, C, Cr, Mn, Ti, Fe, and the like may be contained. The content of B+C+Cr+Mn+Ti+Fe (the total amount of B, C, Cr, Mn, Ti, and Fe) is preferably from 0% to 40%, from 0% to 30%, from 0% to 20%, from 0% to 10%, from 0% to 5%, or from 0% to 1%, and particularly preferably from 0% to less than 1%. When the content of these components is too large, the amorphous state tends to become unstable. Note that, the content of each component of B, C, Cr, Mn, Ti, and Fe is preferably from 0% to 10%, from 0% to 5%, or from 0% to 1%, and particularly from 0% to less than 1%.

As is a component that tends to stabilize the amorphous state of the phase change material. However, As is a toxic component. As such, from the viewpoint of reducing the burden to the environment, the content of As is preferably 30% or less, 25% or less, 20% or less, 10% or less, 5% or less, or 3% or less, and As is particularly preferably substantially not contained. In the present specification, “substantially not contained” means a content of 0.1% or less.

The content of Sb+As (the total amount of Sb and As) is preferably from 0% to less than 5%, from 0% to 4%, or from 0% to 3%, and particularly preferably from 0% to 2%. This makes it easy to reduce the burden to the environment while suppressing a decrease in the crystallization temperature.

Cd, Tl, and Pb are preferably substantially not contained. This can further reduce the burden to the environment.

The phase change material according to the present invention has the above-described configuration, and thus the crystallization temperature can be easily increased. Specifically, the crystallization temperature Tx may be 150° C. or higher, 160° C. or higher, 170° C. or higher, 175° C. or higher, 180° C. or higher, 185° C. or higher, 190° C. or higher, 195° C. or higher, 200° C. or higher, or 205° C. or higher, and in particular 210° C. or higher. As such, the amorphous state is easily stabilized, and the heat resistance of the phase change material is easily improved. Note that, in order for Δ(Tm−Tx) to be a desired value, the upper limit of the crystallization temperature Tx may be, for example, 400° C. or lower, or 350° C. or lower, and in particular 300° C. or lower.

The phase change material according to the present invention has the above-described configuration, and thus the crystalline melting point can be easily lowered. Specifically, the crystalline melting point Tm is preferably 600° C. or lower, 550° C. or lower, 500° C. or lower, 450° C. or lower, 430° C. or lower, or 410° C. or lower, and particularly preferably 400° C. or lower. This makes it easy to reduce the energy required for the phase change. Note that, in order for Δ(Tm−Tx) to be a desired value, the lower limit of the crystalline melting point Tm is preferably, for example, 250° C. or higher, 260° C. or higher, 280° C. or higher, 300° C. or higher, 320° C. or higher, 340° C. or higher, or 360° C. or higher, and particularly preferably 370° C. or higher.

The phase change material according to the present invention has the above-described configuration, and thus can achieve both high crystallization temperature and low crystalline melting point. Therefore, Δ(Tm−Tx), the difference between the crystalline melting point Tm and the crystallization temperature Tx, may be 400° C. or lower, 350° C. or lower, 300° C. or lower, 250° C. or lower, 200° C. or lower, 190° C. or lower, 180° C. or lower, 170° C. or lower, 160° C. or lower, and in particular 150° C. or lower. The lower limit of Δ(Tm−Tx) may be, for example, 50° C. or higher, and in particular 80° C. or higher.

In the phase change material according to the present invention, Te/Ge, a content ratio of Te to Ge, is preferably from 2 to 8, from 3 to 7, or from 4 to 7, and particularly preferably from 4 to 6.5. When Te/Ge satisfies the above value, the phase change material tends to contain GeTe₄ crystals when in the crystalline state.

When in the crystalline state, the phase change material preferably contains at least one type of crystal selected from GeTe₄, GeTe, Te, and Ga, Te₃ as the main component, and particularly preferably contains GeTe crystals as the main component. Here, “containing crystals as the main component” means a state in which the intensity of the first peak in XRD is twice or more the intensity of the first peak of other crystal components. The crystalline melting point of GeTe₄ crystals is about 380° C., which is lower than the crystalline melting point (630° C.) of the crystals precipitated from GST which has been used thus far. Therefore, the phase change material containing GeTe₄ crystals requires less amount of energy for the phase transition from the crystalline state to the amorphous state, and thus power consumption can be reduced. Note that, the phase change material may contain crystals other than the main component. For example, the phase change material may contain GeTe₄ crystals as the main component and at least one type of crystal selected from GeTe, Te, and Ga₂ Te₃.

The phase change material according to the present invention is preferably used in a target. Moreover, the phase change material according to the present invention is preferably used in a thin film. The target is preferably, for example, a sputtering target. The thin film is preferably, for example, a memory layer of a memory element to be described later. Using the phase change material according to the present invention in these applications can suitably contribute to the capacity increase of phase change memories. In other words, the target and the thin film using the phase change material according to the present invention can suitably contribute to the capacity increase of phase change memories.

The phase change material according to the present invention can be produced, for example, as follows. First, raw materials are blended to give a desired composition. Next, the blended raw materials are put into a quartz glass ampoule which has been evacuated while being heated, and the ampoule is sealed with an oxygen burner while being evacuated. Next, the sealed quartz glass ampoule is held at approximately from 650° C. to 1000° C. for from 6 hours to 12 hours. Thereafter, rapid cooling to room temperature was performed, resulting in an amorphous phase change material in a bulk state.

Note that the phase change material according to the present invention is not limited to being amorphous and in a bulk state. For example, a phase change material that is a powder sintered compact can be produced by mixing raw materials to give a homogeneous mixture with a desired composition and then subjecting the mixture to hot-press molding.

The raw materials may be elemental raw materials (Ge, Ga, Si, Te, Ag, I, or the like), or may be compound raw materials (GeTe₄, Ga₂Te₃, AgI, or the like). The foregoing may be used in combination.

For example, using the resulting phase change material as a sputtering target can form a thin film (memory layer) having the above-described composition. The sputtering target can be a powder sintered compact of the phase change material. The sputtering target may be used in the amorphous state or in the crystalline state. For example, when the phase change material in a bulk state is used as the sputtering target, the powder sintered compact can be prepared by pulverizing the phase change material in a bulk state in an inert atmosphere to prepare a fine powder, and then subjecting the fine powder to hot-press molding. Note that, using the amorphous phase change material makes it easy to produce a sputtering target in which components are evenly dispersed.

Note that the sputtering target may be a pure element target (Ge, Te, Sb, Si, Al, Ga, Sn, Bi, Cu, Ag, Zn, Y, In, Ca, or Mg). Alternatively, the thin film having the above-described composition may be formed by adjusting the composition by appropriately adjusting the film formation output with a multi-source sputtering method using a binary alloy target or a ternary (or higher) alloy target.

A method of producing the thin film is not limited, and a chemical vapor deposition (CVD) method, an atomic layer deposition (ALD) method, or the like can be selected in addition to the sputtering method. In particular, the sputtering method is preferable because of the ease of composition control and film thickness control.

As described above, the phase change material according to the present invention contains, in at %, from 1% to 40% of Ge, from 40% to 90% of Te, and from 0% to less than 5% of Sb, and further contains from 1% to 59% of one or more selected from Si, Al, Ga, Sn, Bi, Cu, Ag, Zn, Y, In, Ca, and Mg. With the above configuration, the phase change material according to the present invention can stabilize the amorphous state and improve the heat resistance. In addition, the phase change material according to the present invention can lower the melting point of the crystalline state, making it possible to reduce the energy required for the phase change from the crystalline state to the amorphous state. Therefore, the phase change material according to the present invention is suitable for capacity increase.

### Memory Element

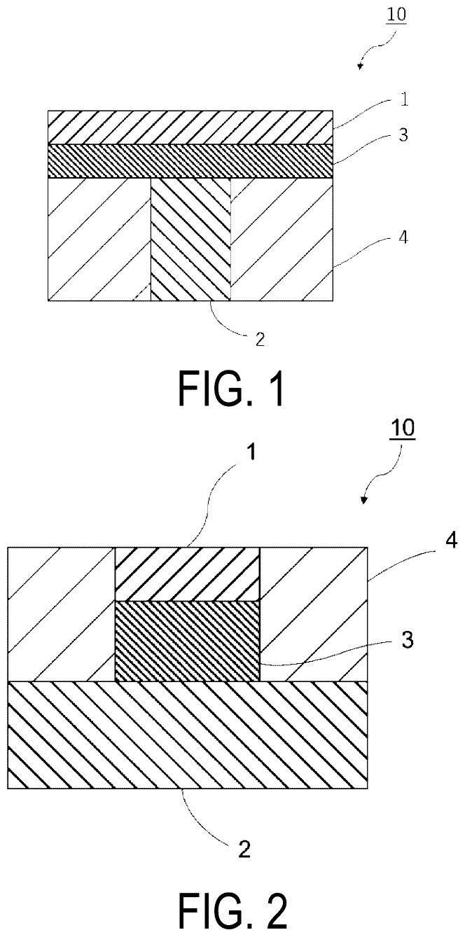

FIG. 1 is a schematic cross-sectional view of a memory element according to a first embodiment of the present invention. A memory element 10 comprises a first electrode 1, a second electrode 2, a memory layer 3, and an insulator 4. The memory layer 3 contains the phase change material according to the present invention. The first electrode 1 is formed at the upper surface of the memory layer 3. The second electrode 2 is formed at the lower surface of the memory layer 3 and is disposed at a position opposite the first electrode 1. The surrounding area of the second electrode 2 is covered with the insulator 4. In this embodiment, the memory layer 3 is disposed between the first electrode 1 and the second electrode 2. The insulator 4 is disposed on the side surface(s) of the second electrode 2.

An inorganic material may be used in the first electrode 1 and the second electrode 2. The inorganic material may be a metal material or a ceramic material. The metal material is preferably, for example, tungsten, titanium, copper, or platinum. The ceramic material is preferably, for example, tungsten nitride or titanium nitride.

The thicknesses of the first electrode 1 and the second electrode 2 may be designed as appropriate. For example, the thicknesses are preferably 200 nm or less, 100 nm or less, 80 nm or less, or 60 nm or less, and particularly preferably 50 nm or less. The smaller the thicknesses, the more advantageous they are for increasing the capacity of memory devices. The lower limit of the thicknesses is, for example, preferably 1 nm or greater, or 2 nm or greater.

As illustrated in FIG. 1, the memory element 10 can record information by applying a predetermined voltage to the memory layer 3 to change the resistance state. More specifically, the method includes a step of recording information by applying a voltage to the memory layer 3 made of phase change material to change the phase of the memory layer 3 from a first state to a second state. Here, the first state and/or the second state means the crystalline state or the amorphous state. Also, the resistance in the crystalline state is lower than that in the amorphous state.

For example, when the memory layer 3 is in the crystalline state, the crystalline state can be changed to the amorphous state by applying a high voltage to the memory layer 3 and performing rapid heating and rapid cooling (first phase change). In this way, the phase of the memory layer 3 can be changed to the amorphous state having high resistance. Note that, in this case, the first state is the crystalline state and the second state is the amorphous state.

When the memory layer 3 is in the amorphous state, the amorphous state can be changed to the crystalline state by applying a voltage lower than that in the first phase change to the memory layer 3 and performing gentle heating and cooling (second phase change). In this way, the phase of the memory layer 3 can be changed to the crystalline state having low resistance. Note that, in this case, the first state is the amorphous state and the second state is the crystalline state.

As described above, the resistance state can be changed by changing the phase of the memory layer 3. In this way, information can be recorded.

In the step of recording information, preferably at least one type of crystal selected from GeTe₄, GeTe, Te, and Ga₂ Te₃ is precipitated. The phase change material containing GeTe₄ crystals requires less amount of energy for the phase transition from the crystalline state to the amorphous state, and thus power consumption of the memory element can be reduced.

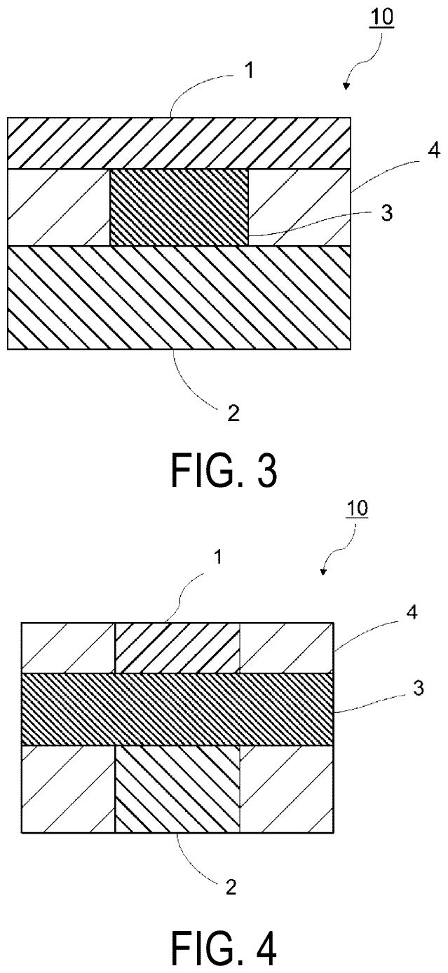

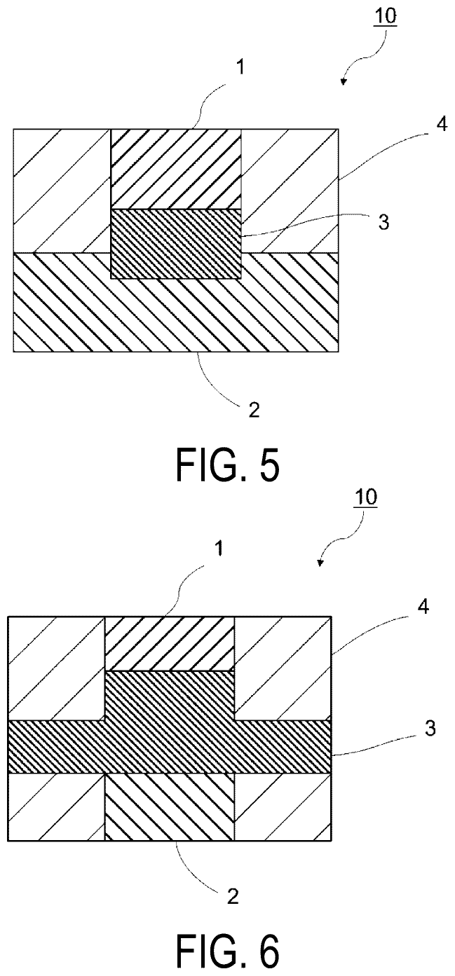

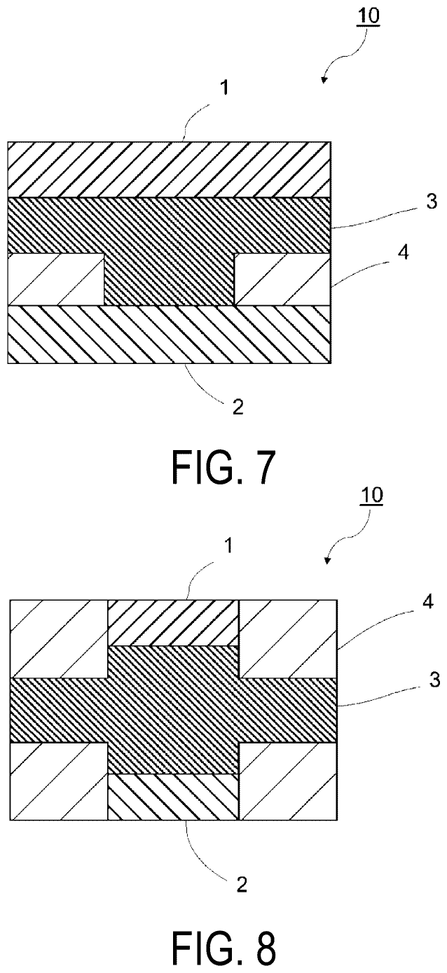

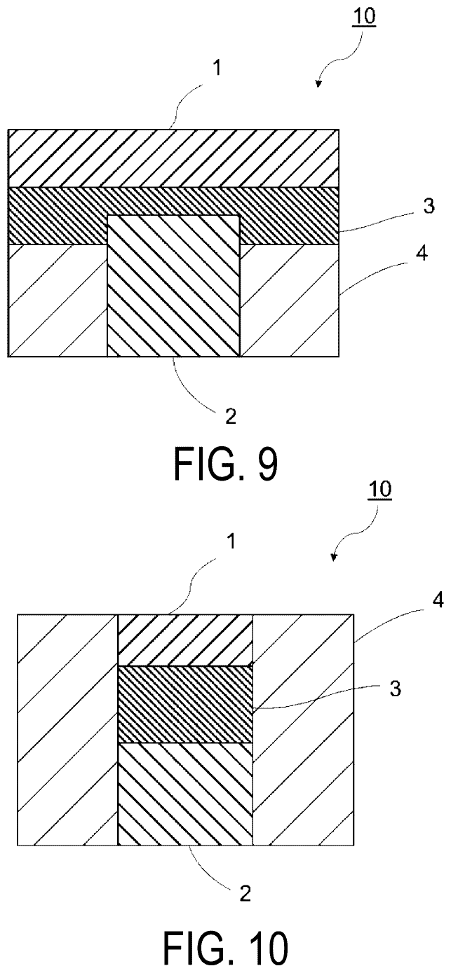

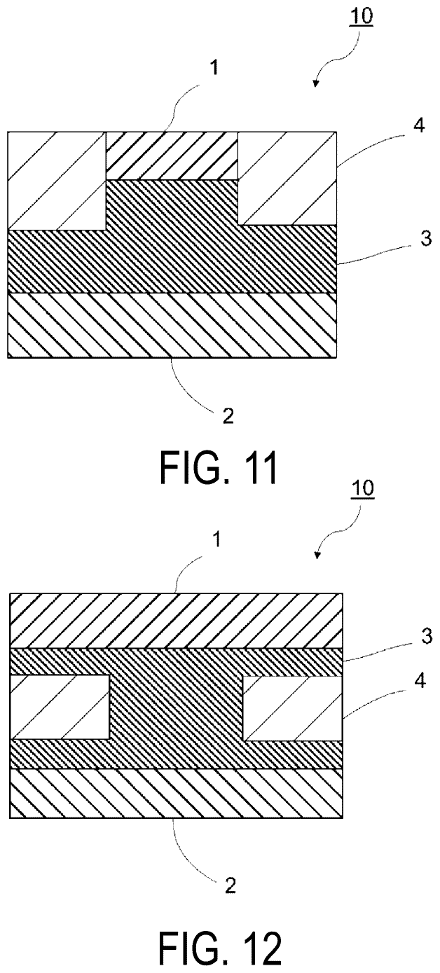

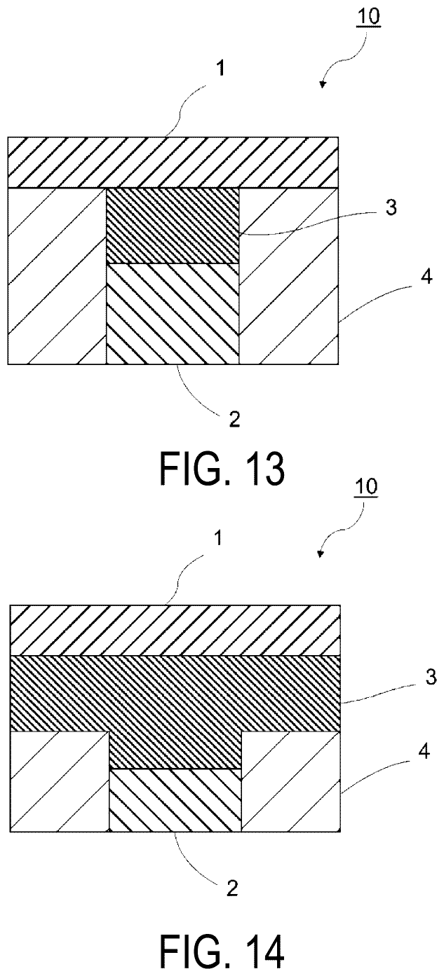

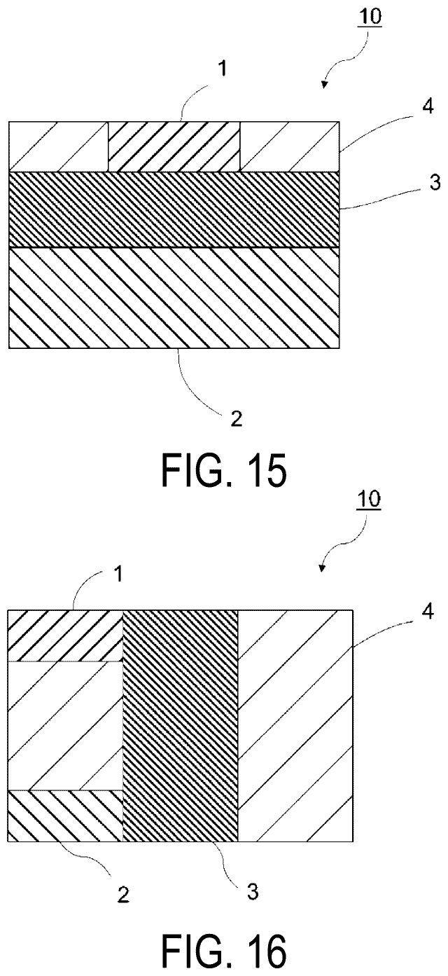

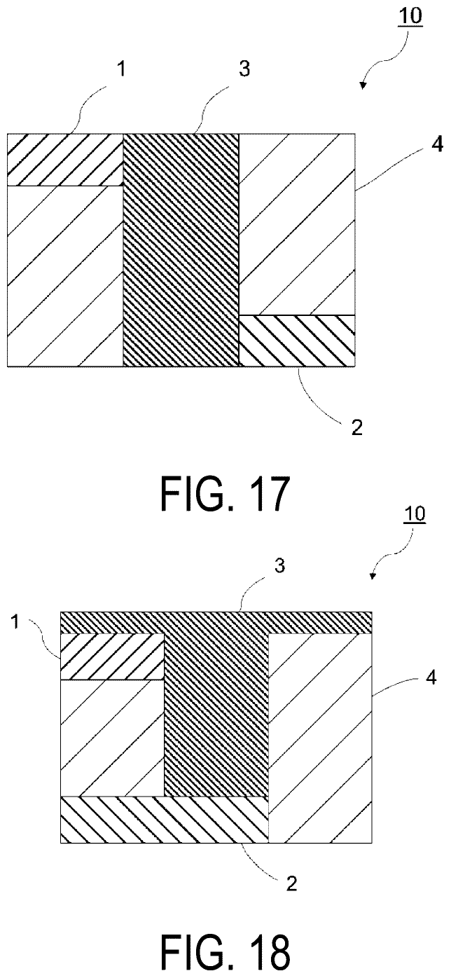

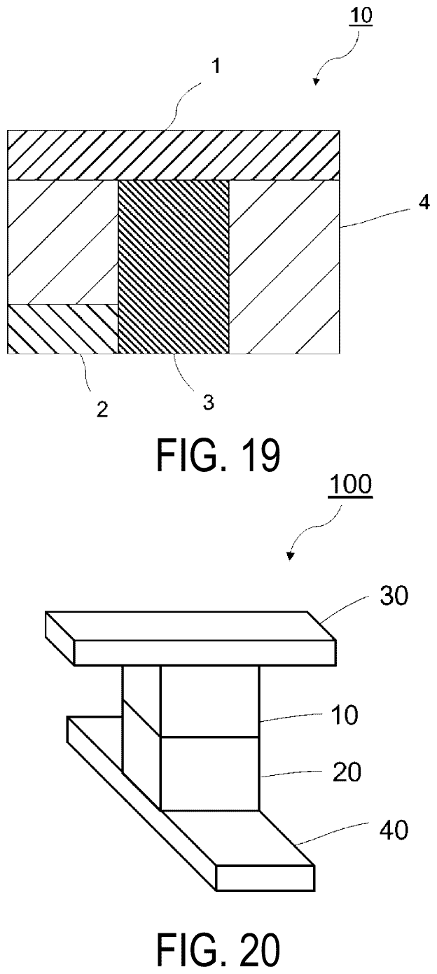

Note that the structure of the memory element is not limited to that illustrated in FIG. 1. FIGS. 2 to 19 are schematic cross-sectional views of memory elements according to a second embodiment to a nineteenth embodiment of the present invention. In the variations of memory elements illustrated in FIGS. 2 to 19, the memory layers 3 also contain the phase change material according to the present invention. Information can be recorded by changing the resistance state of the memory layers 3.

For example, FIG. 2 is a schematic cross-sectional view of a memory element according to the second embodiment of the present invention. In the memory element illustrated in FIG. 2, the insulator 4 is disposed on the side surfaces of both the first electrode 1 and the memory layer 3. In this embodiment, information can be recorded also by changing the resistance state of the memory layer 3.

### Memory Device

FIG. 20 is a schematic three-dimensional view of a memory device according to the present invention. As illustrated in FIG. 20, a memory device 100 includes the memory element 10, a switch element 20, a wordline 30, and a bitline 40. The bitline 40 is orthogonal to the wordline 30 in plan view. The memory element 10 is disposed at the intersection of the wordline 30 and the bitline 40 in plan view. The storage device 100 according to the present embodiment is a so-called crosspoint memory device.

### Examples

Hereinafter, the present invention will be described based on Examples, but the present invention is not limited to Examples below.

Tables 1 to 14 presents Examples 1 to 21. Examples 23 to 113 and Comparative Example 22 of the present invention.

TABLE 1

| | | Examples | | | | | | | |
|---|---|---|---|---|---|---|---|---|---|
| | | 1 | 2 | 3 | 4 | 5 | 6 | 7 | 8 |
| Material | Ge | 15 | 17.5 | 12.5 | 15 | 15 | 12.5 | 17.5 | 15 |
| Composition | Te | 75 | 75 | 75 | 75 | 75 | 75 | 75 | 75 |
| (at %) | Sb | 0 | 0 | 0 | 0 | 0 | 0 | 0 | 0 |
| | Ga | 5 | 2.5 | 7.5 | 2.5 | 7.5 | 5 | 5 | 0 |
| | Ag | 5 | 5 | 5 | 7.5 | 2.5 | 7.5 | 2.5 | 10 |

| | | | | | | | | |
|---|---|---|---|---|---|---|---|---|
| Te/Ge | 5.0 | 4.3 | 6.0 | 5.0 | 5.0 | 6.0 | 4.3 | 5.0 |
| Ga + Ag | 10.0 | 7.5 | 12.5 | 10.0 | 10.0 | 12.5 | 7.5 | 10.0 |
| Crystallization | 245 | 230 | 260 | 218 | 263 | 236 | 251 | 184 |
| Temperature Tx | | | | | | | | |
| Crystalline | 390 | 379 | 389 | 374 | 394 | 384 | 404 | 366 |
| Melting Point Tm | | | | | | | | |
| Δ(Tm − Tx) | 145 | 149 | 129 | 156 | 131 | 148 | 153 | 182 |

TABLE 2

| | | Examples | | | | | | | |
|---|---|---|---|---|---|---|---|---|---|
| | | 9 | 10 | 11 | 12 | 13 | 14 | 15 | 16 |
| Material | Ge | 15 | 10 | 10 | 15 | 15 | 15 | 15 | 27.5 |
| Composition | Te | 75 | 75 | 75 | 72.5 | 77.5 | 72.5 | 67.5 | 61.5 |
| (at %) | Sb | 0 | 0 | 0 | 0 | 0 | 0 | 0 | 0 |
| | Ga | 10 | 5 | 10 | 5 | 5 | 7.5 | 5 | 11 |
| | Ag | 0 | 10 | 5 | 7.5 | 2.5 | 5 | 12.5 | 0 |

| | | | | | | | | |
|---|---|---|---|---|---|---|---|---|
| Te/Ge | 5.0 | 7.5 | 7.5 | 4.8 | 5.2 | 4.8 | 4.5 | 2.2 |
| Ga + Ag | 10.0 | 15.0 | 15.0 | 12.5 | 7.5 | 12.5 | 17.5 | 11.0 |
| Crystallization | 278 | 235 | 261 | 245 | 241 | 263 | 238 | 285 |
| Temperature Tx | | | | | | | | |
| Crystalline | 399 | 370 | 394 | 286 | 375 | 387 | 375 | 416 |
| Melting Point Tm | | | | | | | | |
| Δ(Tm − Tx) | 121 | 135 | 133 | 41 | 134 | 124 | 137 | 131 |

TABLE 3

| | | | | | | | Comparative | | |
|---|---|---|---|---|---|---|---|---|---|
| | | Examples | | | | | Example | Examples | |
| | | 17 | 18 | 19 | 20 | 21 | 22 | 23 | 24 |
| Material | Ge | 22.5 | 12.5 | 10 | 20 | 33 | 22 | 25 | 15 |
| Composition | Te | 47.5 | 47.5 | 40 | 55 | 66 | 56 | 57.5 | 57.5 |
| (at %) | Sb | 0 | 0 | 0 | 0 | 0 | 22 | 0 | 0 |
| | Ga | 12.5 | 17.5 | 25 | 15 | 1 | 0 | 15 | 15 |
| | Ag | 17.5 | 22.5 | 25 | 10 | 0 | 0 | 2.5 | 12.5 |

| | | | | | | | | |
|---|---|---|---|---|---|---|---|---|
| Te/Ge | 2.1 | 3.8 | 4.0 | 2.8 | 2.0 | 2.5 | 2.3 | 3.8 |
| Ga + Ag | 30.0 | 40.0 | 50.0 | 25.0 | 1.0 | 0.0 | 17.5 | 27.5 |
| Crystallization | 244 | 250 | 252 | 265 | 233 | 160 | 270 | 221 |
| Temperature Tx | | | | | | | | |
| Crystalline | 388 | 390 | 387 | 402 | 378 | 630 | 408 | 389 |
| Melting Point Tm | | | | | | | | |
| Δ(Tm − Tx) | 144 | 140 | 135 | 137 | 145 | 470 | 138 | 168 |

TABLE 4

| | | Examples | | | | | | | |
|---|---|---|---|---|---|---|---|---|---|
| | | 25 | 26 | 27 | 28 | 29 | 30 | 31 | 32 |
| Material | Ge | 15 | 15 | 25 | 15 | 15.8 | 15.4 | 15 | 15 |
| Composition | Te | 57.5 | 47.5 | 47.5 | 47.5 | 78.9 | 76.9 | 57.5 | 67.5 |
| (at %) | Sb | 0 | 0 | 0 | 0 | 0 | 0 | 0 | 0 |
| | Ga | 25 | 25 | 15 | 15 | 0 | 7.7 | 5 | 15 |
| | Ag | 2.5 | 12.5 | 12.5 | 22.5 | 5.3 | 0 | 22.5 | 2.5 |

| | | | | | | | | |
|---|---|---|---|---|---|---|---|---|
| Te/Ge | 3.8 | 3.2 | 1.9 | 3.2 | 5.0 | 5.0 | 3.8 | 4.5 |
| Ga + Ag | 27.5 | 37.5 | 27.5 | 37.5 | 5.3 | 7.7 | 27.5 | 17.5 |
| Crystallization | 243 | 217 | 223 | 202 | 200 | 240 | 210 | 232 |
| Temperature Tx | | | | | | | | |
| Crystalline | 383 | 392 | 410 | 380 | 371 | 373 | 398 | 372 |
| Melting Point Tm | | | | | | | | |
| Δ(Tm − Tx) | 140 | 175 | 187 | 178 | 171 | 133 | 188 | 140 |

TABLE 5

| | | Examples | | | | | | | | | |
|---|---|---|---|---|---|---|---|---|---|---|---|
| | | 33 | 34 | 35 | 36 | 37 | 38 | 39 | 40 | 41 | 42 |
| Material | Ge | 5 | 5 | 25 | 27.5 | 35 | 15 | 22.5 | 22.5 | 20 | 25 |
| Composition | Te | 57.5 | 67.5 | 60 | 57.5 | 47.5 | 52.5 | 55 | 55 | 57.5 | 57.5 |
| (at %) | Sb | 0 | 0 | 0 | 0 | 0 | 0 | 0 | 0 | 0 | 0 |
| | Ga | 15 | 15 | 15 | 15 | 15 | 20 | 15 | 20 | 15 | 5 |
| | Ag | 22.5 | 12.5 | 0 | 0 | 2.5 | 12.5 | 7.5 | 2.5 | 7.5 | 12.5 |

| | | | | | | | | | | |
|---|---|---|---|---|---|---|---|---|---|---|
| Te/Ge | 11.5 | 13.5 | 2.4 | 2.1 | 1.4 | 3.5 | 2.4 | 2.4 | 2.9 | 2.3 |
| Ga + Ag | 37.5 | 27.5 | 15.0 | 15.0 | 17.5 | 32.5 | 22.5 | 22.5 | 22.5 | 17.5 |
| Crystallization | 204 | 218 | 267 | 243 | 223 | 223 | 256 | 251 | 262 | 232 |
| Temperature Tx | | | | | | | | | | |
| Crystalline | 410 | 430 | 410 | 413 | 423 | 382 | 392 | 398 | 386 | 394 |
| Melting Point Tm | | | | | | | | | | |
| Δ(Tm − Tx) | 206 | 212 | 143 | 170 | 200 | 159 | 136 | 147 | 124 | 162 |

TABLE 6

| | | Examples | | | | | |
|---|---|---|---|---|---|---|---|
| | | 43 | 44 | 45 | 46 | 47 | 48 |
| Material | Ge | 11.9 | 11.2 | 14.3 | 13.4 | 14.8 | 14.6 |
| Composition | Te | 68.7 | 65.1 | 68.7 | 65.1 | 66.8 | 65.8 |
| (at %) | Sb | 0 | 0 | 0 | 0 | 0 | 0 |
| | Zn | 5 | 10 | 5 | 10 | 1 | 2.5 |
| | Ga | 11.9 | 11.2 | 9.5 | 9 | 5 | 4.9 |
| | Ag | 2.5 | 2.5 | 2.5 | 2.5 | 12.4 | 12.2 |

| | | | | | | |
|---|---|---|---|---|---|---|
| Te/Ge | 5.8 | 5.8 | 4.8 | 4.9 | 4.5 | 4.5 |
| Ga + Ag | 14.4 | 13.7 | 12.0 | 11.5 | 17.4 | 17.1 |
| Crystallization | 247 | 245 | 249 | 241 | 239 | 238 |
| Temperature Tx | | | | | | |
| Crystalline | 392 | 394 | 391 | 388 | 385 | 387 |
| Melting Point Tm | | | | | | |
| Δ(Tm − Tx) | 145 | 149 | 142 | 147 | 146 | 149 |

TABLE 7

| | | Examples | | | | | | | | |
|---|---|---|---|---|---|---|---|---|---|---|
| | | 49 | 50 | 51 | 52 | 53 | 54 | 55 | 56 | 57 |
| Material | Ge | 7.5 | 2.5 | 10 | 5 | 21.1 | 15.85 | 17.1 | 14.6 | 14.6 |
| Composition | Te | 72.5 | 72.5 | 72.5 | 72.5 | 52.8 | 70.6 | 68.1 | 70.6 | 68.1 |
| (at %) | Sb | 0 | 0 | 0 | 0 | 0 | 0 | 0 | 0 | 0 |
| | Si | 5 | 10 | 5 | 10 | 21.1 | 5 | 5 | 5 | 5 |
| | Ga | 12.5 | 12.5 | 10 | 10 | 5 | 8.55 | 9.8 | 9.8 | 12.3 |
| | Ag | 2.5 | 2.5 | 2.5 | 2.5 | 0 | 0 | 0 | 0 | 0 |

| | | | | | | | | | |
|---|---|---|---|---|---|---|---|---|---|
| Te/Ge | 9.7 | 29.0 | 7.3 | 14.5 | 2.5 | 4.5 | 4.0 | 4.8 | 4.7 |
| Ga + Ag | 15.0 | 15.0 | 12.5 | 12.5 | 5.0 | 8.6 | 9.8 | 9.8 | 12.3 |
| Crystallization | 314 | 328 | 314 | 345 | 324 | 302 | 304 | 305 | 312 |
| Temperature Tx | | | | | | | | | |
| Crystalline | 433 | 442 | 431 | 441 | 467 | 422 | 411 | 420 | 423 |
| Melting Point Tm | | | | | | | | | |
| Δ(Tm − Tx) | 119 | 114 | 117 | 96 | 143 | 120 | 107 | 115 | 111 |

TABLE 8

| | | Examples | | | | | | | |
|---|---|---|---|---|---|---|---|---|---|
| | | 58 | 59 | 60 | 61 | 62 | 63 | 64 | 65 |
| Thin Film | Ge | 15.4 | 17.2 | 12.3 | 14.9 | 15.2 | 11.9 | 17.8 | 15.3 |
| Composition | Te | 77.3 | 77 | 77.1 | 80.1 | 76.2 | 80.8 | 75.9 | 81.6 |
| (at %) | Sb | 0 | 0 | 0 | 0 | 0 | 0 | 0 | 0 |
| | Ga | 5.4 | 3.6 | 8.3 | 2.3 | 6.8 | 4.9 | 4.4 | 0 |
| | Ag | 1.9 | 2.2 | 2.3 | 2.7 | 1.8 | 2.4 | 1.9 | 3.1 |

| | | | | | | | | |
|---|---|---|---|---|---|---|---|---|
| Te/Ge | 5.0 | 4.5 | 6.3 | 5.4 | 5.0 | 6.8 | 4.3 | 5.3 |
| Ga + Ag | 7.3 | 5.8 | 10.6 | 5.0 | 8.6 | 7.3 | 6.3 | 3.1 |

TABLE 9

| | | Examples | | | | | | | |
|---|---|---|---|---|---|---|---|---|---|
| | | 66 | 67 | 68 | 69 | 70 | 71 | 72 | 73 |
| Thin Film | Ge | 14.8 | 9.9 | 9.9 | 14.6 | 15.1 | 15.2 | 14.9 | 27.2 |
| Composition | Te | 75.3 | 81.2 | 77.2 | 77.9 | 78.3 | 75 | 75.2 | 61.4 |
| (at %) | Sb | 0 | 0 | 0 | 0 | 0 | 0 | 0 | 0 |
| | Ga | 9.9 | 5.5 | 10.7 | 4.9 | 4.7 | 7.5 | 5.8 | 11.4 |
| | Ag | 0 | 3.4 | 2.2 | 2.6 | 1.9 | 2.3 | 4.1 | 0 |

| | | | | | | | | |
|---|---|---|---|---|---|---|---|---|
| Te/Ge | 5.1 | 8.2 | 7.8 | 5.3 | 5.2 | 4.9 | 5.0 | 2.3 |
| Ga + Ag | 9.9 | 8.9 | 12.9 | 7.5 | 6.6 | 9.8 | 9.9 | 11.4 |

TABLE 10

| | | Examples | | | | | | |
|---|---|---|---|---|---|---|---|---|
| | | 74 | 75 | 76 | 77 | 78 | 79 | 80 |
| Thin Film | Ge | 22.4 | 12.6 | 10.2 | 19.9 | 31.2 | 22.1 | 15 |
| Composition | Te | 59.6 | 64.7 | 58.4 | 62 | 66.3 | 58.3 | 65 |
| (at %) | Sb | 0 | 0 | 0 | 0 | 0 | 0 | 0 |
| | Ga | 12.9 | 17.1 | 25.2 | 14.6 | 2.5 | 16.8 | 17 |
| | Ag | 5.1 | 5.6 | 6.2 | 3.5 | 0 | 2.8 | 3 |

| | | | | | | | |
|---|---|---|---|---|---|---|---|
| Te/Ge | 2.7 | 5.1 | 5.7 | 3.1 | 2.1 | 2.6 | 4.3 |
| Ga + Ag | 18.0 | 22.7 | 31.4 | 18.1 | 2.5 | 19.6 | 20.0 |

TABLE 11

| | | Examples | | | | | | | |
|---|---|---|---|---|---|---|---|---|---|
| | | 81 | 82 | 83 | 84 | 85 | 86 | 87 | 88 |
| Thin Film | Ge | 14.8 | 14.3 | 25.3 | 14.9 | 16.6 | 15.1 | 13.2 | 15.3 |
| Composition | Te | 56.2 | 57.9 | 56.4 | 65 | 81.2 | 77.4 | 77.2 | 70.2 |
| (at %) | Sb | 0 | 0 | 0 | 0 | 0 | 0 | 0 | 0 |
| | Ga | 27 | 24.9 | 15.1 | 14.5 | 0 | 7.5 | 4.8 | 12.4 |
| | Ag | 2 | 2.9 | 3.2 | 5.6 | 2.2 | 0 | 4.8 | 2.1 |

| | | | | | | | | |
|---|---|---|---|---|---|---|---|---|
| Te/Ge | 3.8 | 4.0 | 2.2 | 4.4 | 4.9 | 5.1 | 5.8 | 4.6 |
| Ga + Ag | 29.0 | 27.8 | 18.3 | 20.1 | 2.2 | 7.5 | 9.6 | 14.5 |

TABLE 12

| | | Examples | | | | | | | | | |
|---|---|---|---|---|---|---|---|---|---|---|---|
| | | 89 | 90 | 91 | 92 | 93 | 94 | 95 | 96 | 97 | 98 |
| Thin Film | Ge | 5.6 | 6.2 | 23.9 | 27.9 | 34.9 | 15.6 | 23.2 | 22.9 | 21.1 | 24.9 |
| Composition | Te | 75.2 | 75.4 | 61.9 | 57.9 | 48.2 | 61.3 | 60.4 | 56.2 | 63.1 | 66.6 |
| (at %) | Sb | 0 | 0 | 0 | 0 | 0 | 0 | 0 | 0 | 0 | 0 |
| | Ga | 15 | 15.6 | 14.2 | 14.2 | 15.1 | 19.9 | 13.7 | 19.2 | 13.2 | 5.3 |
| | Ag | 4.2 | 2.8 | 0 | 0 | 1.8 | 3.2 | 2.7 | 1.7 | 2.6 | 3.2 |

| | | | | | | | | | | |
|---|---|---|---|---|---|---|---|---|---|---|
| Te/Ge | 13.4 | 12.2 | 2.6 | 2.1 | 1.4 | 3.9 | 2.6 | 2.5 | 3.0 | 2.7 |
| Ga + Ag | 19.2 | 18.4 | 14.2 | 14.2 | 16.9 | 23.1 | 16.4 | 20.9 | 15.8 | 8.5 |

TABLE 13

| | | Examples | | | | | |
|---|---|---|---|---|---|---|---|
| | | 99 | 100 | 101 | 102 | 103 | 104 |
| Thin Film | Ge | 11.2 | 11.4 | 13.9 | 13.2 | 14.4 | 14.5 |
| Composition | Te | 69.2 | 66.2 | 69.9 | 66.2 | 75.3 | 72.9 |
| (at %) | Sb | 0 | 0 | 0 | 0 | 0 | 0 |
| | Zn | 4.2 | 9.8 | 4.7 | 10.3 | 1.2 | 2.6 |
| | Ga | 13.6 | 10.7 | 10.6 | 8.5 | 5.7 | 5.5 |
| | Ag | 1.8 | 1.9 | 1.9 | 1.8 | 3.4 | 4.5 |

| | | | | | | |
|---|---|---|---|---|---|---|
| Te/Ge | 6.2 | 5.8 | 5.0 | 5.0 | 5.2 | 5.0 |
| Ga + Ag | 15.4 | 12.6 | 12.5 | 10.3 | 9.1 | 10.0 |

TABLE 14

| | | Examples | | | | | | | | |
|---|---|---|---|---|---|---|---|---|---|---|
| | | 105 | 106 | 107 | 108 | 109 | 110 | 111 | 112 | 113 |
| Thin Film | Ge | 7.3 | 2.4 | 9.9 | 5.1 | 22.1 | 15.7 | 17.4 | 14.2 | 14.1 |
| Composition | Te | 73.1 | 72.9 | 72.6 | 72.7 | 53.4 | 71.2 | 68.3 | 70.9 | 69.1 |
| (at %) | Sb | 0 | 0 | 0 | 0 | 0 | 0 | 0 | 0 | 0 |
| | Si | 5.1 | 10.3 | 5.4 | 9.8 | 20.7 | 5.3 | 5.1 | 5.2 | 5.5 |
| | Ga | 12.3 | 12.5 | 10 | 10.1 | 3.8 | 7.8 | 9.2 | 9.7 | 11.3 |
| | Ag | 2.2 | 1.9 | 2.1 | 2.3 | 0 | 0 | 0 | 0 | 0 |

| | | | | | | | | | |
|---|---|---|---|---|---|---|---|---|---|
| Te/Ge | 10.0 | 30.4 | 7.3 | 14.3 | 2.4 | 4.5 | 3.9 | 5.0 | 4.9 |
| Ga + Ag | 14.5 | 14.4 | 12.1 | 12.4 | 3.8 | 7.8 | 9.2 | 9.7 | 11.3 |

Samples of Examples were prepared as follows. First, a quartz glass ampoule was evacuated while being heated, and then raw materials were mixed to give a composition presented in Tables 1 to 7. Then, the raw materials were put into the quartz glass ampoule. The quartz glass ampoule was then sealed using an oxygen burner. Next, the sealed quartz glass ampoule was placed in a melting furnace, heated to from 650° C. to 1000° C. at a rate of from 10° C. to 40° C./hour, and then held for from 6 hours to 12 hours. During the holding time, the quartz glass ampoule was turned upside down, and the melt was stirred. Finally, the quartz glass ampoule was removed from the melting furnace and rapidly cooled to room temperature, resulting in a sample.

The crystallization temperature Tx and the crystalline melting point Tm of the resulting sample were measured using DTA. Δ(Tm−Tx), a difference between Tm and Tx, was calculated.

Literature values of the crystallization temperature Tx and the crystalline melting point Tm of Ge₂₂Sb₂₂ Te₅₆ (GST) were used in Comparative Example.

Next, the resistance-variable material was formed into a film having a thickness of 150 nm, resulting in a thin film. The composition after film formation was determined using SEM-EDX. The obtained film compositions are presented in Tables 8 to 14. Note that, the film formation was performed by Ar sputtering under a reduced-pressure atmosphere.

Tables 1 to 7 indicate that the phase change materials of Examples 1 to 21 and Examples 23 to 57 had a higher crystallization temperature Tx and a lower crystalline melting point Tm when compared to GST. Further, the phase change materials of Examples 1 to 21 and Examples 23 to 57 had a Δ(Tm−Tx) smaller than that of GST. In addition, the thin films of Examples 58 to 113 presented in Tables 8 to 14 were able to be prepared.

### INDUSTRIAL APPLICABILITY

The phase change material according to the present invention can be suitably used in a memory element, a memory device, a sputtering target that can be used in the production of the foregoing, and the like.

### REFERENCE SIGNS LIST

1 First Electrode
2 Second Electrode
3 Memory Layer
4 Insulator
10 Memory Element
20 Switch Element
30 Wordline
40 Bitline
100 Memory Device

1. A phase change material comprising, in at %, from 1% to 40% of Ge, from 40% to 90% of Te, and from 0% to less than 5% of Sb, and
further comprising from 1% to 59% of one or more selected from Si, Al, Ga, Sn, Bi, Cu, Ag, Zn, Y, In, Ca, and Mg.

2. The phase change material according to claim 1, wherein Te/Ge, a content ratio of Te to Ge, is from 2 to 8.

3. The phase change material according to claim 1, comprising from 0% to less than 5% of Sb+As.

4. The phase change material according to claim 1, wherein a crystallization temperature Tx is 150° C. or higher.

5. The phase change material according to claim 1, wherein a crystalline melting point Tm is 600° C. or lower.

6. The phase change material according to claim 1, wherein Δ(Tm−Tx), a difference between the crystalline melting point Tm and the crystallization temperature Tx, is 400° C. or lower.

7. A phase change material comprising, in at %, from 1% to 40% of Ge, from 40% to 90% of Te, from 41% to 99% of Ge+Te, and from 0% to less than 5% of Sb,
wherein Δ(Tm−Tx), a difference between a crystalline melting point Tm and a crystallization temperature Tx, is 400° C. or lower.

8. A phase change material comprising, in at %, from 1% to 40% of Ge, from 40% to 90% of Te, from 41% to 99% of Ge+Te, from 0% to less than 5% of Sb, and from 0% to 59% of Ga,
wherein when in a crystalline state, the phase change material comprises at least one type of crystal selected from GeTe₄, GeTe, Te, and Ga₂Te₃.

9. A target comprising the phase change material according to claim 1.

10. A thin film comprising the phase change material according to claim 1.

11. A memory element comprising the phase change material according to claim 1.

12. A memory device comprising the memory element according to claim 11.

13. A method of recording information, the method comprising
a step of recording information by applying a voltage to a memory layer comprising a phase change material and changing a phase of the memory layer from a first state to a second state,
wherein the memory layer comprises a phase change material comprising, in at %, from 1% to 40% of Ge, from 40% to 90% of Te, and from 0% to less than 5% of Sb, and further comprises from 1% to 59% of one or more selected from Si, Al, Ga, Sn, Bi, Cu, Ag, Zn, Y, In, Ca, and Mg.

14. The method according to claim 13, wherein in the step of recording information, at least one type of crystal selected from GeTe₄, GeTe, Te, and Ga₂Te₅ is precipitated.
